(19) United States
(12) Patent Application Publication
(10) Pub. No.: US 2026/0329364 A1
(43) Pub. Date: Oct. 22, 2026

(54) Server Power Supply Circuit and Control Method

(71) Applicant: SUZHOU METABRAIN INTELLIGENT TECHNOLOGY CO., LTD., Suzhou, Jiangsu (CN)

(72) Inventors: Jianyu LI, Suzhou, Jiangsu (CN); Deyang HUA, Suzhou, Jiangsu (CN); Lingyan WANG, Suzhou, Jiangsu (CN); Dongyu ZHANG, Suzhou, Jiangsu (CN)

(73) Assignee: SUZHOU METABRAIN INTELLIGENT TECHNOLOGY CO., LTD., Suzhou, Jiangsu (CN)

(21) Appl. No.: 19/113,289

(22) PCT Filed: Aug. 28, 2024
(86) PCT No.: PCT/CN2024/115231

§ 371 Date: Mar. 19, 2025

(30) Foreign Application Priority Data
Sep. 11, 2023 (CN) 202311163226.9

(51) Int. Cl. G06F 1/3246; G06F 1/3206; H05K 7/14

(52) U.S. Cl. CPC G06F 1/3246; G06F 1/3206; H05K 7/1492

(57) ABSTRACT

A server power supply circuit and a control method are provided. The server power supply circuit includes: a voltage conversion module, a power-down holding module, and a control module, wherein an input end of the voltage conversion module is connected to the power-down holding module to convert an input voltage into a target voltage; the power-down holding module includes an energy storage element and a power supply element, wherein the energy storage element stores energy provided by the input voltage of the circuit and transfers the energy to the power supply element; the power supply element forms a voltage by releasing the energy transferred by the energy storage element; and the control module is respectively connected to the voltage conversion module and the power-down holding module to control an access state of the power-down holding module according to current state information.

### CROSS-REFERENCE TO RELATED APPLICATIONS

The present disclosure is a national stage filing under 35 U.S.C. § 371 of international application number PCT/CN2024/115231, filed Aug. 28, 2024, which claims priority to Chinese Patent Application No. 202311163226.9, filed to the China National Intellectual Property Administration on Sep. 11, 2023 and entitled “Server Power Supply Circuit and Control Method”, which is incorporated herein by reference in its entirety.

### TECHNICAL FIELD

The present disclosure relates to the technical field of server power supplies, and in particular, to a server power supply circuit and a control method.

### BACKGROUND

As a Power Support Unit (PSU) of a server, a server power supply needs to have high reliability, which requires the server power supply to detect and report relevant input and output states in real time, provide the relevant input and output states for the server, and at the same time to process abnormalities occurring in time to avoid the spread of the abnormalities, thereby avoiding greater accidents or greater losses. Especially when a power-down abnormality occurs in an input voltage of the server power supply, the server power supply cannot supply power to the server normally, so that the server cannot back up relevant data in the server in time when the server power supply cannot supply power to the server, and the reliability of the server power supply is reduced.

### SUMMARY

In view of this, the present disclosure provides a server power supply circuit and a control method, so as to solve the problems that a server cannot back up data in time when a power-down abnormality occurs in an input voltage of a server power supply, and the reliability of the server power supply is low.

In a first aspect, the present disclosure provides a server power supply circuit, which includes: a voltage conversion module, a power-down holding module, and a control module.

An input end of the voltage conversion module is connected to the power-down holding module. The voltage conversion module is configured to convert an input voltage of the voltage conversion module into a target voltage. The target voltage is configured to supply power to a server.

The power-down holding module is configured to hold the magnitude of the target voltage when an input voltage of the circuit is powered down. The power-down holding module includes an energy storage element and a power supply element.

A first end of the energy storage element is connected to an input end of the circuit, and a second end of the energy storage element is connected to the input end of the voltage conversion module. The energy storage element is configured to store energy provided by the input voltage of the circuit and transfer the energy to the power supply element.

A first end of the power supply element is connected to the input end of the circuit, and a second end of the power supply element is connected to the input end of the voltage conversion module. The power supply element forms a voltage by releasing the energy transferred by the energy storage element, so as to hold the voltage input into the voltage conversion module when the input voltage of the circuit is powered down, thereby holding the magnitude of the target voltage.

The control module is respectively connected to the voltage conversion module and the power-down holding module, and the control module is configured to collect current state information of the circuit, and control an access state of the power-down holding module according to the current state information, so as to turn on the power-down holding module when the input voltage of the circuit is powered down.

Therefore, the access state of the power-down holding module may be controlled by means of the current state information collected by the control module, so that the magnitude of the target voltage is held when the input voltage of the circuit is powered down, a certain time is provided for the server to back up data, and the reliability of the server power supply circuit is improved.

In an embodiment, the power-down holding module further includes a diversion switch. The diversion switch is configured to control the frequency and duration of energy transfer from the energy storage element to the power supply element, so as to control the magnitude of the voltage provided by the power supply element.

A first end of the diversion switch is connected to the second end of the energy storage element, and a second end of the diversion switch is connected to the first end of the power supply element.

In a case that the diversion switch is turned on, the energy storage element stores the energy provided by the input voltage of the circuit.

In a case that the diversion switch is disconnected, the energy storage element transfers the energy to the power supply element, and the power supply element forms the voltage by releasing the energy transferred by the energy storage element.

Therefore, the magnitude of the voltage provided by the power supply element may be controlled by the diversion switch, so that the magnitude of the voltage input into the voltage conversion module is held when the input voltage of the circuit is powered down, thereby holding the magnitude of the target voltage.

In an embodiment, the circuit further includes a power-down holding switch.

A first end of the power-down holding switch is connected to the power-down holding module, a second end of the power-down holding switch is connected to the voltage conversion module, and a third end of the power-down holding switch is connected to the control module.

The control module controls the connection and/or disconnection between the power-down holding module and the voltage conversion module through the power-down holding switch, so as to control the access state of the power-down holding module.

In an embodiment, the power-down holding switch is a transistor.

The control module controls the transistor to be turned on, and controls the power-down holding module and the voltage conversion module to be connected, so as to control the power-down holding module to be turned on.

And/or, the control module controls the transistor to be turned off, and controls the power-down holding module and the voltage conversion module to be disconnected, so as to control the power-down holding module to be turned off.

Therefore, the connection or disconnection between the power-down holding module and the voltage conversion module may be controlled by the power-down holding switch, thereby controlling the access state of the power-down holding module.

In an embodiment, the circuit further includes a hot-swap module. The hot-swap module is respectively connected to the control module and the voltage conversion module.

The hot-swap module is configured to suppress a current spike generated by an input current when the circuit is hot-swapped.

The control module is configured to control an access state of the hot-swap module.

Therefore, the current spike generated by the input current when the circuit is hot-swapped may be suppressed by means of connecting the hot-swap module to the circuit, so that the stability of the input current is ensured, and the fluctuation in the current output by the server power supply circuit is avoided.

In an embodiment, the control module includes a first controller and a second controller. The first controller and the second controller are electrically isolated and in communication connection.

The current state information includes an input voltage and a first temperature at the input end of the circuit, and an output current and a second temperature at an output end of the voltage conversion module.

The first controller is connected to the input end of the circuit, and the first controller is configured to collect the input voltage and the first temperature.

The second controller is connected to the output end of the voltage conversion module, and the second controller is configured to collect the output current and the second temperature.

Therefore, the relevant states of the input end and the output end of the voltage conversion module may be respectively collected by the first controller and the second controller, thereby ensuring sampling of each link of the server power supply and collection of the state information while forming electrical isolation to avoid the fault of the input end of the server power supply circuit from affecting the output end.

In an embodiment, the first controller is connected to the input end of the voltage conversion module.

The first controller determines an operating state of the circuit according to the input voltage, and controls the access state of the power-down holding module, the hot-swap module, and/or the voltage conversion module.

Therefore, the power-down holding module and the hot-swap module can be controlled by the first controller, so that the abnormality generated by the server power supply circuit is processed in time, thereby improving the reliability of the server power supply circuit.

In an embodiment, the first controller determines the operating state of the circuit according to the first temperature, and controls the access state of the voltage conversion module.

The second controller determines the operating state of the voltage conversion module according to the output current and the second temperature, and controls the access state of the voltage conversion module.

Therefore, the voltage conversion module can be controlled by the first controller and the second controller, so that the abnormality generated by the server power supply circuit is processed in time, thereby improving the reliability of the server power supply circuit.

In a second aspect, the present disclosure provides a control method for a server power supply circuit. The method is applied to the server power supply circuit in the first aspect or any corresponding implementation thereof, and includes the following operations.

Current state information of the server power supply circuit is acquired.

An access state of a power-down holding module is controlled based on the current state information.

Therefore, the current access state of the power-down holding module can be controlled by means of the current state information collected by a control module, so that the magnitude of a target voltage is held when an input voltage of the circuit is powered down, a certain time is provided for a server to back up data, and the reliability of the server power supply circuit is improved.

In an embodiment, the current state information includes an input voltage at an input end of the server power supply circuit. The operation that an access state of a power-down holding module is controlled based on the current state information includes the following operations.

In a case that the input voltage is less than a first preset voltage, it is determined that an operating state of the server power supply circuit is a power-down state, and input under-voltage alarm information is sent.

The power-down holding module and a voltage conversion module are controlled to be connected, by controlling a power-down holding switch to be turned on, so as to turn on the power-down holding module.

Therefore, in a case that the input voltage of the server power supply circuit is in the power-down state but is still not under-voltage, the voltage input into the voltage conversion module may be maintained by the power-down holding module to ensure the magnitude of the target voltage output by the server power supply circuit. At the same time, the input under-voltage alarm information is sent to remind a user side to check and adjust the input voltage in time, so that the under-voltage of the input voltage is avoided.

In an embodiment, the operation that an access state of a power-down holding module is controlled based on the current state information further includes the following operations.

In a case that the input voltage is greater than or equal to the first preset voltage, it is determined that the operating state of the server power supply circuit is a normal state.

The power-down holding module and the voltage conversion module are controlled to be disconnected, by controlling the power-down holding switch to be turned off, so as to turn off the power-down holding module.

Therefore, the power-down holding module may be turned off when the input voltage of the server power supply circuit returns to normal.

In an embodiment, the operation that an access state of a power-down holding module is controlled based on the current state information further includes the following operations.

In a case that the input voltage is less than a second preset voltage, it is determined that the operating state of the server power supply circuit is a complete power-down state, and input under-voltage fault information is sent. The second preset voltage is less than the first preset voltage.

The power-down holding module and the voltage conversion module are controlled to be disconnected, by controlling the power-down holding switch to be turned off, so as to turn off the power-down holding module.

Therefore, in a case that the input voltage of the server power supply circuit is in the complete power-down state, and the magnitude of the target voltage output by the server power supply circuit cannot be maintained by only replying on the power-down holding module, the power-down holding module is also turned off, and the input under-voltage fault information is sent to remind the user side to check and adjust the input voltage in time.

In an embodiment, the method further includes the following operation.

An access state of a hot-swap module and/or the voltage conversion module is controlled based on the current state information.

Therefore, the access state of the hot-swap module and/or the voltage conversion module may be controlled by means of the current state information, so as to respond to and process the abnormality in the server power supply circuit in time.

In an embodiment, the current state information includes an input voltage at an input end of the server power supply circuit. The operation that an access state of a hot-swap module and/or the voltage conversion module is controlled based on the current state information includes the following operations.

In a case that the input voltage is less than a third preset voltage, it is determined that the operating state of the server power supply circuit is an under-voltage state, and input under-voltage fault information is sent. The third preset voltage is less than the first preset voltage and greater than the second preset voltage.

The hot-swap module and the voltage conversion module are controlled to be turned off.

Therefore, in a case that the input voltage of the service power circuit is in the under-voltage state, the hot-swap module and the voltage conversion module may be turned off, the magnitude of the target voltage output by the server power supply circuit is maintained by replying on the power-down holding module. At the same time, the input under-voltage fault information is sent to remind the user side to check and adjust the input voltage in time, so as to avoid the under-voltage of the input voltage all the time or even complete power down.

In an embodiment, the current state information includes an output current of the voltage conversion module. The operation that an access state of a hot-swap module and/or the voltage conversion module is controlled based on the current state information includes the following operation.

In a case that the output current is greater than a first preset current, it is determined that the operating state of the voltage conversion module is an over-current alarm state, and output over-current alarm information is sent.

Therefore, in a case that the output current of the voltage conversion module is in the over-current alarm state, the output over-current alarm information may be sent to remind the user side to check and adjust the voltage conversion module in time.

In an embodiment, the operation that an access state of a hot-swap module and/or the voltage conversion module is controlled based on the current state information further includes the following operations.

In a case that the output current is greater than a second preset current, it is determined that the operating state of the voltage conversion module is an over-current fault state, and output over-current fault information is sent. The second preset current is greater than the first preset current.

The voltage conversion module is controlled to be turned off.

Therefore, in a case that the output current of the voltage conversion module is in the over-current fault state, the voltage conversion module may be turned off to avoid further faults and damage to related components caused by the over-current of the output current. At the same time, the output over-current fault information is sent to remind the user side to check and adjust the voltage conversion module in time.

In an embodiment, the current state information includes a first temperature of an input end of the server power supply circuit. The operation that an access state of a hot-swap module and/or the voltage conversion module is controlled based on the current state information includes the following operation.

In a case that the first temperature is greater than a first preset temperature, it is determined that the operating state of the server power supply circuit is an over-temperature alarm state, and first over-temperature alarm information is sent.

Therefore, in a case that the temperature of the server power supply circuit is in the over-temperature alarm state, the first over-temperature alarm information may be sent to remind the user side to check and adjust the server power supply circuit in time.

In an embodiment, the operation that an access state of a hot-swap module and/or the voltage conversion module is controlled based on the current state information further includes the following operations.

In a case that the first temperature is greater than a second preset temperature, it is determined that the operating state of the server power supply circuit is an over-temperature fault state, and first over-temperature fault information is sent. The second preset temperature is greater than the first preset temperature.

The voltage conversion module is controlled to be turned off.

Therefore, in a case that the temperature of the server power supply circuit is in the over-temperature fault state, the voltage conversion module may be turned off to avoid further faults and damage to the related components caused by excessive temperature. At the same time, the first over-temperature fault information is sent to remind the user side to check and adjust the server power supply circuit in time.

In an embodiment, the current state information includes a second temperature of the voltage conversion module. The operation that an access state of a hot-swap module and/or the voltage conversion module is controlled based on the current state information includes the following operation.

In a case that the second temperature is greater than a third preset temperature, it is determined that the operating state of the voltage conversion module is an over-temperature alarm state, and second over-temperature alarm information is sent.

Therefore, in a case that the temperature of the voltage conversion module is in the over-temperature alarm state, the first over-temperature alarm information may be sent to remind the user side to check and adjust the server power supply circuit in time.

In an embodiment, the operation that an access state of a hot-swap module and/or the voltage conversion module is controlled based on the current state information further includes the following operations.

In a case that the second temperature is greater than a fourth preset temperature, it is determined that that the operating state of the voltage conversion module is an over-temperature fault state, and second over-temperature fault information is sent. The fourth preset temperature is greater than the third preset temperature.

The voltage conversion module is controlled to be turned off.

Therefore, in a case that the temperature of the voltage conversion module is in the over-temperature fault state, the voltage conversion module may be turned off to avoid further faults and damage to the related components caused by excessive temperature. At the same time, the first over-temperature fault information is sent to remind the user side to check and adjust the server power supply circuit in time.

In an embodiment, the operation that current state information of the server power supply circuit is acquired includes the following operations.

State information of the server power supply circuit is acquired at preset time intervals.

Averaging processing is performed on the acquired preset number of state information, and the state information after the averaging processing is used as current state information.

Therefore, the current state information may be obtained by a method of multiple sampling and averaging, so as to avoid the problem of inaccurate data obtained by single sampling, and improving the reliability and accuracy of the control of the server power supply circuit.

### BRIEF DESCRIPTION OF THE DRAWINGS

In order to more clearly illustrate the specific embodiments of the present disclosure or the technical solutions in the related art, the drawings used in the description of the specific embodiments or the related art will be briefly described below. It is apparent that the drawings described below are only some embodiments of the present disclosure. Other drawings may further be obtained by those of ordinary skill in the art according to these drawings without creative efforts.

FIG. 1 is a schematic structural diagram of a server power supply circuit according to an embodiment of the present disclosure.

FIG. 2 is a circuit diagram of a server power supply circuit according to an embodiment of the present disclosure.

FIG. 3 is a schematic structural diagram of another server power supply circuit according to an embodiment of the present disclosure.

FIG. 4 is a schematic flowchart of a control method for a server power supply circuit according to an embodiment of the present disclosure.

FIG. 5 is a flowchart of a specific embodiment of a control method for a server power supply circuit according to an embodiment of the present disclosure.

FIG. 6 is a schematic flowchart of another control method for a server power supply circuit according to an embodiment of the present disclosure.

### The Reference Signs Are Further Described Below.

100—Voltage conversion module; 200—Power—down holding circuit; 210—Energy storage element; 220—Power supply element; 230—Diversion switch; 300—Control module; 310—First controller; 320—Second controller; 400—Power-down holding switch; 500—Hot-swap module.

### Detailed Description of the Embodiments

In order to make the purposes, technical solutions and advantages of embodiments of the present disclosure clearer, the technical solutions in the embodiments of the present disclosure will be clearly and completely described in conjunction with the drawings in the embodiments of the present disclosure. It is apparent that the described embodiments are only a part of the embodiments of the present disclosure, and not all of them. All other embodiments obtained by those skilled in the art on the basis of the embodiments in the present disclosure without creative work shall fall within the scope of protection of the present disclosure.

As a PSU of a server, a server power supply is a digital power supply with high power density and complex functions. The PSU currently used on the server uses 220 V AC or 380 V DC as input, and converts same into 12 V or 54 V low-voltage DC for output, so as to supply power to the server. In the related art, in order to ensure the stability of the power supply of the server power supply, the server power supply can not only provide voltage and current output with sufficient power for the server, but also usually has certain information detection and reporting functions, and can collect temperature, voltage and current information for the input and output of the server power supply, and other relevant input and output state parameters. After the server power supply detects and reports relevant input and output states, the server determines the reported input and output states, which leads to a lag in determination and processing of an abnormality or a fault in the server power supply, thereby reducing the reliability of the server power supply. At the same time, since when a power-down abnormality occurs in an input voltage of the server power supply, the server power supply cannot supply power to the server normally, resulting in the server power supply being unable to supply power to the server and the server being unable to back up relevant data in the server in time, thereby reducing the reliability of the server power supply.

In order to solve the above problems, the embodiments of the present disclosure provide a server power supply circuit and a control method. In an aspect, the embodiments of the present disclosure provide a server power supply circuit, which includes: a voltage conversion module 100, a power-down holding module 200, and a control module 300. An input end of the voltage conversion module 100 is connected to the power-down holding module 200. The voltage conversion module 100 is configured to convert an input voltage of the voltage conversion module 100 into a target voltage. The target voltage is configured to supply power to a server. The power-down holding module 200 is configured to hold the magnitude of the target voltage when an input voltage of the circuit is powered down. The power-down holding module 200 includes an energy storage element 210 and a power supply element 220. A first end of the energy storage element 210 is connected to an input end of the circuit, and a second end of the energy storage element 210 is connected to the input end of the voltage conversion module 100. The energy storage element 210 is configured to store energy provided by the input voltage of the circuit and transfer the energy to the power supply element 220. A first end of the power supply element 220 is connected to the input end of the circuit, and a second end of the power supply element 220 is connected to the input end of the voltage conversion module 100. The power supply element 220 forms a voltage by releasing the energy transferred by the energy storage element 210, so as to hold the voltage input into the voltage conversion module 100 when the input voltage of the circuit is powered down, thereby holding the magnitude of the target voltage. The control module 300 is respectively connected to the voltage conversion module 100 and the power-down holding module 200, and the control module 300 is configured to collect current state information of the circuit, and control an access state of the power-down holding module 200 according to the current state information, so as to turn on the power-down holding module 200 when the input voltage of the circuit is powered down. Therefore, the access state of the power-down holding module 200 can be controlled by means of the current state information collected by the control module 300, so that the magnitude of the target voltage is held when the input voltage of the circuit is powered down, a certain time is provided for the server to back up data, and the reliability of the server power supply circuit is improved.

In another aspect, the embodiments of the present disclosure provide a control method for a server power supply circuit. The method is applied to the server power supply circuit, and includes: acquiring current state information of the server power supply circuit; and controlling an access state of a power-down holding module 200 based on the current state information. Therefore, the access state of the power-down holding module 200 can be controlled by means of the current state information collected by a control module 300, so that the magnitude of a target voltage is held when an input voltage of the circuit is powered down, a certain time is provided for the server to back up data, and the reliability of the server power supply circuit is improved.

According to the embodiments of the present disclosure, the embodiment of the server power supply circuit is provided, and the term “module” used below may realize a combination of software and/or hardware with a predetermined function. It is to be noted that the terms “first”, “second” and the like in the specification, claims and the above drawings of the present disclosure are used for distinguishing similar objects rather than describing a specific sequence or a precedence order. It should be understood that the data used in such a way may be exchanged where appropriate, in order that the embodiments of the present disclosure described here can be implemented in an order other than those illustrated or described herein. In addition, terms “include” and “have” and any variations thereof are intended to cover non-exclusive inclusions. For example, it is not limited for processes, methods, systems, products or servers containing a series of steps or units to clearly list those steps or units, and other steps or units which are not clearly listed or are inherent to these processes, methods, products or devices may be included instead.

In the present embodiment, a server power supply circuit is provided. FIG. 1 is a schematic structural diagram of a server power supply circuit according to an embodiment of the present disclosure. As shown in FIG. 1, the circuit includes: a voltage conversion module 100, a power-down holding module 200, and a control module 300.

An input end of the voltage conversion module 100 is connected to the power-down holding module 200. The voltage conversion module 100 is configured to convert an input voltage of the voltage conversion module 100 into a target voltage. The target voltage is configured to supply power to a server.

The power-down holding module 200 is configured to hold the magnitude of the target voltage when an input voltage of the circuit is powered down. The power-down holding module 200 includes an energy storage element 210 and a power supply element 220. A first end of the energy storage element 210 is connected to an input end of the circuit, and a second end of the energy storage element 210 is connected to the input end of the voltage conversion module 100. The energy storage element 210 is configured to store energy provided by the input voltage of the circuit and transfer the energy to the power supply element 220. A first end of the power supply element 220 is connected to the input end of the circuit, and a second end of the power supply element 220 is connected to the input end of the voltage conversion module 100. The power supply element 220 forms a voltage by releasing the energy transferred by the energy storage element 210, so as to hold the voltage input into the voltage conversion module 100 when the input voltage of the circuit is powered down, thereby holding the magnitude of the target voltage.

The control module 300 is respectively connected to the voltage conversion module 100 and the power-down holding module 200, and the control module 300 is configured to collect current state information of the circuit, and control an access state of the power-down holding module 200 according to the current state information, so as to turn on the power-down holding module 200 when the input voltage of the circuit is powered down.

Through the above circuit structure, the access state of the power-down holding module 200 may be controlled by means of the current state information collected by the control module 300, so that the magnitude of the target voltage is held when the input voltage of the circuit is powered down, a certain time is provided for the server to back up data, and the reliability of the server power supply circuit is improved.

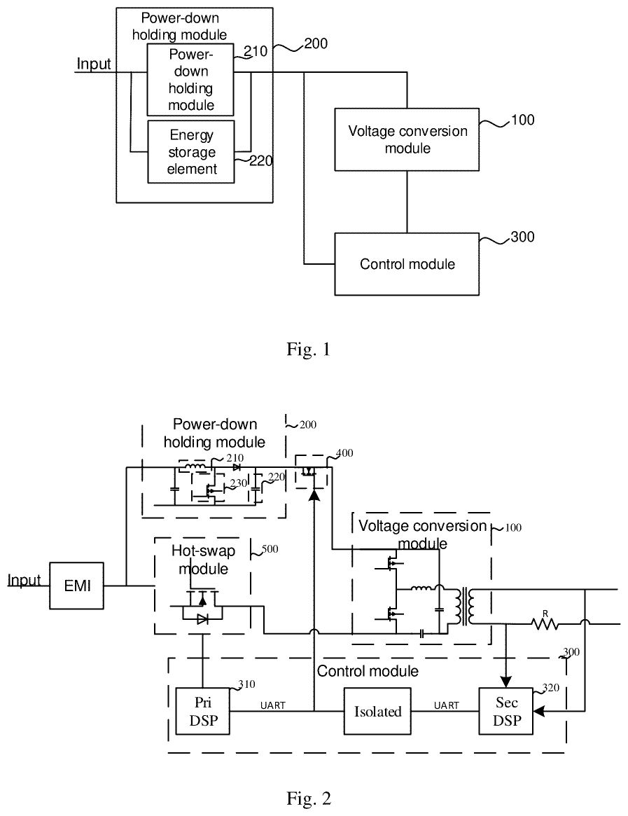

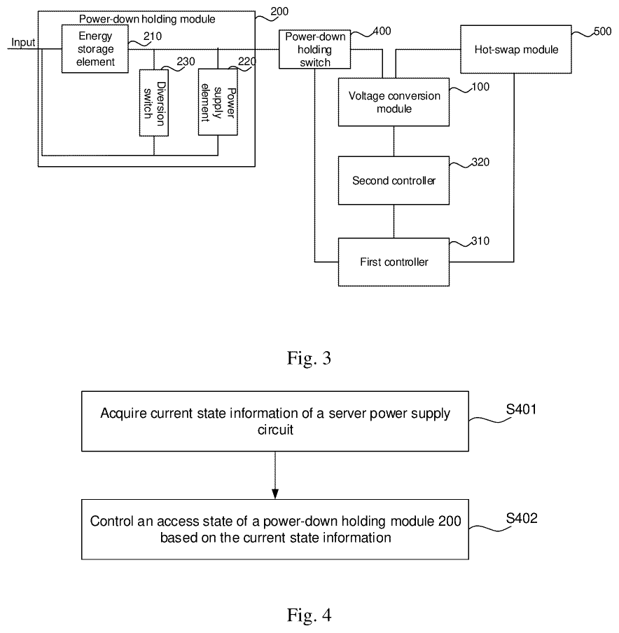

In an embodiment, FIG. 2 is a circuit diagram of a server power supply circuit according to an embodiment of the present disclosure. It is to be noted that FIG. 2 only gives a brief circuit diagram of relevant modules and a connection relationship between the modules. The actual server power supply circuit may include more devices or modules. FIG. 3 is a schematic structural diagram of another server power supply circuit according to an embodiment of the present disclosure. As shown in FIG. 2 and FIG. 3, the power-down holding module 200 may further include a diversion switch 230. The diversion switch 230 is configured to control the frequency and duration of energy transfer from the energy storage element 210 to the power supply element 220, so as to control the magnitude of the voltage provided by the power supply element 220. A first end of the diversion switch 230 is connected to the second end of the energy storage element 210, and a second end of the diversion switch 230 is connected to the first end of the power supply element 220. In a case that the diversion switch 230 is turned on, the energy storage element 210 stores the energy provided by the input voltage of the circuit. In a case that the diversion switch 230 is disconnected, the energy storage element 210 transfers the energy to the power supply element 220, and the power supply element 220 forms the voltage by releasing the energy transferred by the energy storage element 210. Therefore, the magnitude of the voltage provided by the power supply element 220 is controlled by the diversion switch 230, so that the magnitude of the voltage input into the voltage conversion module 100 is held when the input voltage of the circuit is powered down, thereby holding the magnitude of the target voltage.

In an embodiment, the control module 300 may also be connected to the diversion switch 230, and the frequency and duration of energy transfer from the energy storage element 210 to the power supply element 220 may be controlled by controlling the on-off frequency of the diversion switch 230, thereby controlling the on-off frequency of the diversion switch 230 in real time according to the power-down situation of the input voltage of the server power supply circuit, so that the voltage output by the power-down holding module 200 to the voltage conversion module 100 can be maintained within a constant range.

In an embodiment, the energy storage element 210 may be an inductor, the power supply element 220 may be a capacitor, and the diversion switch 230 may be a transistor.

In an embodiment, the power-down holding module 200 may further include a filter capacitor and a diode. A first end of the filter capacitor is connected to the first end of the energy storage element 210, and a second end of the filter capacitor is connected to the second end of the diversion switch 230. The filter capacitor is configured to filter out the voltage input into the power-down holding module 200, that is, the noise interference of the input voltage of the server power supply circuit, so as to improve the stability of the voltage output by the power-down holding module 200. A first end of the diode is connected to the second end of the energy storage element 210, and a second end of the diode is connected to the second end of the power supply element 220. The diode is configured to prevent the power supply element 220 from discharging to the ground when the diversion switch 230 is turned off.

In an embodiment, as shown in FIG. 2 and FIG. 3, the server power supply circuit further includes a power-down holding switch 400. A first end of the power-down holding switch 400 is connected to the power-down holding module 200, a second end of the power-down holding switch 400 is connected to the voltage conversion module 100, and a third end of the power-down holding switch 400 is connected to the control module 300. The control module 300 may control the connection and/or disconnection between the power-down holding module 200 and the voltage conversion module 100 through the power-down holding switch 400, so as to control the access state of the power-down holding module 200.

In an embodiment, as shown in FIG. 2, the power-down holding switch 400 may be a transistor. In some embodiments, the control module 300 controls the transistor to be turned on, and controls the power-down holding module 200 and the voltage conversion module 100 to be connected, so as to control the power-down holding module 200 to be turned on. The control module 300 controls the transistor to be turned off, and controls the power-down holding module 200 and the voltage conversion module 100 to be disconnected, so as to control the power-down holding module 200 to be turned off. Therefore, the connection or disconnection between the power-down holding module 200 and the voltage conversion module 100 is controlled by the power-down holding switch 400, thereby controlling the access state of the power-down holding module 200.

In an embodiment, the power-down holding switch 400 may also be another electrically controlled switch or a digital switch.

In an embodiment, as shown in FIG. 2 and FIG. 3, the server power supply circuit may further include a hot-swap module 500. The hot-swap module 500 is respectively connected to the control module 300 and the voltage conversion module 100. The hot-swap module 500 is configured to suppress a current spike generated by an input current when the circuit is hot-swapped. The control module 300 is configured to control an access state of the hot-swap module 500. Therefore, the current spike generated by the input current when the circuit is hot-swapped is suppressed by means of connecting the hot-swap module 500 to the circuit, so that the stability of the input current is ensured, and the fluctuation in the current output by the server power supply circuit is avoided.

In an embodiment, as shown in FIG. 2, the hot-swap module 500 may suppress the current spike generated by the input current when the circuit is hot-swapped through a first transistor or an electromagnetic relay, so that the stability of the input current is ensured, and the fluctuation in the current output by the server power supply circuit is avoided. Correspondingly, the hot-swap module 500 may further include devices or functional units for realizing other auxiliary functions in addition to the first transistor or the electromagnetic relay.

In an embodiment, as shown in FIG. 2, the voltage conversion module 100 may be, but is not limited to, a Low Loss Converter (LLC) half-bridge resonant converter or a phase-shifted full-bridge converter, etc., which may be arranged as a circuit structure for DC voltage conversion.

In an embodiment, as shown in FIG. 2, the server power supply circuit may further include an electromagnetic interference filtering module, corresponding to an Electromagnetic Interference (EMI) part in FIG. 2, the electromagnetic interference filtering module is configured to filter out electromagnetic interference in the input voltage of the server power supply circuit, and may filter out high-order harmonics and high-frequency harmonics of the input voltage, thereby achieving electromagnetic compatibility and ensuring the normal operation of the server power supply circuit.

In an embodiment, as shown in FIG. 2 and FIG. 3, the control module 300 includes a first controller 310 and a second controller 320. The first controller 310, that is, Pri DSP in FIG. 3, and the second controller 320, that is, Sec DSP in FIG. 3, are electrically isolated by an isolator Isolated, and a communication connection is realized based on a Universal Asynchronous Receiver/Transmitter (UART) serial port protocol. The current state information includes an input voltage and a first temperature at the input end of the server power supply circuit, and an output voltage and a second temperature at an output end of the voltage conversion module 100. Then in some embodiments, the first controller 310 is connected to the input end of the server power supply circuit to collect the input voltage and the first temperature at the input end of the circuit. The second controller 320 is connected to the output end of the voltage conversion module 100 to collect the output current and the second temperature at the output end of the voltage conversion module 100. Therefore, the relevant states of the input end and the output end of the voltage conversion module 100 may be respectively collected by the first controller 310 and the second controller 320, thereby ensuring sampling of each link of the server power supply and collection of the state information while forming electrical isolation to avoid the fault of the input end of the server power supply circuit from affecting the output end.

In an embodiment, the first controller 310 is connected to the input end of the voltage conversion module 100. The first controller 310 determines an operating state of the circuit according to the input voltage, and controls the access state of the power-down holding module 200, the hot-swap module 500, and/or the voltage conversion module 100. Therefore, the power-down holding module 200 and the hot-swap module 500 can be controlled by the first controller 310, so that the voltage abnormality generated by the server power supply circuit is processed in time, thereby improving the reliability of the server power supply circuit.

In an embodiment, the first controller 310 determines the operating state of the circuit according to the first temperature, and controls the access state of the voltage conversion module 100. The second controller 320 determines the operating state of the voltage conversion module 100 according to the output current and the second temperature, and controls the access state of the voltage conversion module 100. Therefore, the voltage conversion module 100 can be controlled by the first controller 310 and the second controller 320, so that the abnormality generated by the server power supply circuit is processed in time, thereby improving the reliability of the server power supply circuit.

According to the embodiments of the present disclosure, an embodiment of a control method for a server power supply circuit is provided. It is to be noted that the steps shown in the flowchart of the drawings may be executed in a computer system, such as a set of computer-executable instructions, and although a logical sequence is shown in the flowchart, in some cases, the steps shown or described may be executed in a different order than here.

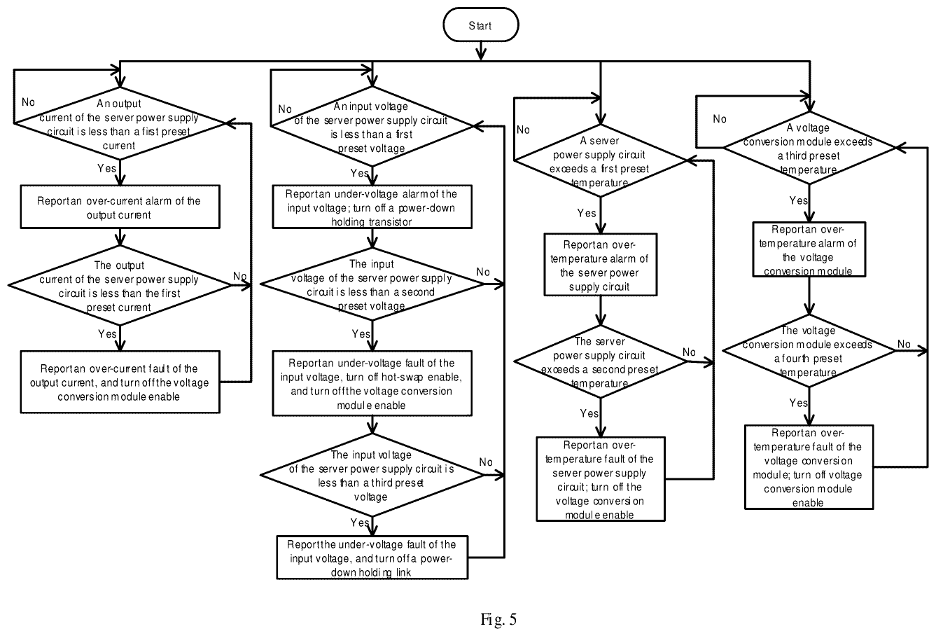

In the present embodiment, a control method for a server power supply circuit is provided, which may be configured for the above server power supply circuit. FIG. 4 is a flowchart of a control method for a server power supply circuit according to an embodiment of the present disclosure. As shown in FIG. 4, the flow includes the following steps.

At S401, current state information of the server power supply circuit is acquired.

In the embodiment of the present disclosure, the current state information is obtained by a control module 300 sampling each link and module in the server power supply circuit, and may include information such as a temperature, a voltage, and a current of each module.

In an embodiment, the current state information may be classified into the current state information obtained by sampling an input end of the server power supply circuit and the current state information obtained by sampling an output end of a voltage conversion module 100. In some embodiments, the current state information obtained by sampling the input end of the server power supply circuit includes an input voltage and a first temperature of the server power supply circuit, which may be obtained by a first controller 310 through sampling. The current state information obtained by sampling the output end of the voltage conversion module 100 includes an output current and a second temperature of the voltage conversion module 100, which may be obtained by a second controller 320 through sampling.

In an embodiment, the output current of the voltage conversion module 100 may be determined by a resistor arranged at the output end of the voltage conversion module 100, and the current flowing through the resistor, that is, the output current, is calculated by sampling a voltage difference across the resistor.

At S402, an access state of a power-down holding module 200 is controlled based on the current state information.

In the embodiment of the present disclosure, the control module 300 controls the access state of the power-down holding module 200 based on the current state information, which is the input voltage of the server power supply circuit in some embodiments. The access state may include on and off, that is, the power-down holding module 200 is controlled to be turned on and turned off.

In an embodiment, the current state information further includes the first temperature of the server power supply circuit, and the output current and the second temperature of the voltage conversion module 100. Correspondingly, for different conditions of the output current, the first temperature, and the second temperature, the control module 300 can also control the access state of a hot-swap module 500 and the voltage conversion module 100.

In an embodiment, in a case that the current state information is the input voltage of the server power supply circuit, the above S402 may be classified into the following cases.

First, in a case that the input voltage is less than a first preset voltage, it is determined that an operating state of the server power supply circuit is a power-down state, and input under-voltage alarm information is sent; and by controlling a power-down holding switch 400 to be turned on, the power-down holding module 200 and the voltage conversion module 100 are controlled to be connected, so as to turn on the power-down holding module 200. The first preset voltage is lower than a normal input voltage of the server power supply circuit, but higher than a voltage in an under-voltage state. At this time, the input voltage of the server power supply circuit may be low due to voltage fluctuations and other reasons. By boosting the input voltage through the power-down control module 300, a voltage value input into the voltage conversion module 100 can be normal, thereby ensuring that a target voltage output by the server power supply circuit is in a normal state. Therefore, in a case that the input voltage of the server power supply circuit is in the power-down state but is still not under-voltage, the voltage input into the voltage conversion module 100 may be maintained by the power-down holding module 200 to ensure the magnitude of the target voltage output by the server power supply circuit, so as to reserve a certain time for a server to back up relevant data therein, thereby avoiding the server being unable to work normally and the data loss caused by the subsequent continuous under-voltage of the input voltage of the server power supply circuit. At the same time, the input under-voltage alarm information is sent to remind a user side to check and adjust the input voltage in time, so that the under-voltage of the input voltage is avoided.

Second, in a case that the input voltage is greater than or equal to the first preset voltage, it is determined that the operating state of the server power supply circuit is a normal state; and by controlling the power-down holding switch 400 to be turned off, the power-down holding module 200 and the voltage conversion module 100 are controlled to be disconnected, so as to turn off the power-down holding module 200. At this time, the input voltage returns to normal, and the power-down holding module 200 is no longer needed to boost the input voltage, so that the power-down holding module 200 is turned off.

Third, in a case that the input voltage is less than a third preset voltage, it is determined that the operating state of the server power supply circuit is an under-voltage state, and input under-voltage fault information is sent; and the hot-swap module 500 and the voltage conversion module 100 are controlled to be turned off. The third preset voltage is less than the first preset voltage and greater than the second preset voltage. The third preset voltage is the input voltage in the under-voltage state. In a case that the input voltage is less than the third preset voltage, it may be confirmed that the input voltage of the server power supply circuit is in the under-voltage state, but is not completely powered down. At this time, it is impossible to increase the voltage value input into the voltage conversion module 100 to a normal value by only relying on the power-down control module 300 to boost the input voltage. Therefore, the hot-swap module 500 and the voltage conversion module 100 are turned off, and the power-down holding module 200 directly outputs the voltage as the output voltage of the server power supply circuit. At the same time, a certain time is also provided for the server to perform an operation of retaining necessary data to avoid data loss caused by sudden power failure. Therefore, in a case that the input voltage of the service power circuit is in the under-voltage state, the hot-swap module 500 and the voltage conversion module 100 are turned off, the magnitude of the target voltage output by the server power supply circuit is maintained by relying on the power-down holding module 200. At the same time, the input under-voltage fault information is sent to remind the user side to check and adjust the input voltage in time, so as to avoid the under-voltage of the input voltage all the time or even complete power down.

Fourth, in a case that the input voltage is less than a second preset voltage, it is determined that the operating state of the server power supply circuit is a complete power-down state, and input under-voltage fault information is sent; and by controlling the power-down holding switch 400 to be turned off, the power-down holding module 200 and the voltage conversion module 100 are controlled to be disconnected, so as to turn off the power-down holding module 200. The second preset voltage is less than the first preset voltage and the third preset voltage, and the second preset voltage is the input voltage in the complete power-down state. At this time, the output voltage of the server power supply circuit cannot be maintained by the voltage directly output by the power-down control module 300, so that the power-down holding module 200 is turned off. Therefore, in a case that the input voltage of the server power supply circuit is in the complete power-down state, and the magnitude of the target voltage output by the server power supply circuit cannot be maintained by only replying on the power-down holding module 200, the power-down holding module 200 is also turned off and the input under-voltage fault information is sent to remind the user side to check and adjust the input voltage in time.

In an embodiment, in a case that the current state information is the output current of the voltage conversion module 100, the above S402 includes the following cases.

First, in a case that the output current is greater than a first preset current, it is determined that the operating state of the voltage conversion module 100 is an over-current alarm state, and output over-current alarm information is sent. The first preset current may be the maximum current value in the normal state. In a case that the output current is greater than the first preset current, the over-current occurs in the voltage conversion module 100, an over-current abnormality occurs, but the voltage conversion module 100 can still work at this time, so that only the output over-current alarm information is sent to remind the user side to check and adjust the voltage conversion module 100 in time.

Second, in a case that the output current is greater than a second preset current, it is determined that the operating state of the voltage conversion module 100 is an over-current fault state, and output over-current fault information is sent; and the voltage conversion module 100 is controlled to be turned off. The second preset current is greater than first preset current. In a case that the output current is greater than the second preset current, it may be determined that the voltage conversion module 100 has an over-current fault. At this time, the voltage conversion module 100 cannot work normally, or even if it can continue to work, an abnormality or a fault is gradually produced due to the over-current fault, or the abnormality is transmitted to the server. Therefore, it is necessary to turn off the voltage conversion module 100 at this time to avoid further faults and damage to related components caused by the over-current of the output current. At the same time, the output over-current fault information is sent to remind the user side to check and adjust the voltage conversion module 100 in time.

Through the above method, the first preset current is set to be a recovery value, and the second preset current is set to be an over-current value, so as to form a hysteresis control. The output current is considered normal only in a case that the output current is lower than the first preset current, so as to ensure that the output current can be truly reduced to the normal current value by adjusting the output current, thereby improving the reliability.

In an embodiment, in a case that the current state information is the first temperature of the server power supply circuit, the above S402 includes the following cases.

First, in a case that the first temperature is greater than a first preset temperature, it is determined that the operating state of the server power supply circuit is an over-temperature alarm state, and first over-temperature alarm information is sent. The first preset temperature may be the maximum temperature value in the normal state. In a case that the first temperature is greater than the first preset temperature, the over-current occurs in the server power supply circuit, an over-current abnormality occurs, but the server power supply circuit can still work at this time, so that only the first over-temperature alarm information is sent to remind the user side to check and adjust the server power supply circuit in time.

Second, in a case that the first temperature is greater than a second preset temperature, it is determined that the operating state of the server power supply circuit is an over-temperature fault state, and first over-temperature fault information is sent; and the voltage conversion module 100 is controlled to be turned off. The second preset temperature is greater than the first preset temperature. In a case that the output temperature is greater than the second preset temperature, it may be determined that the server power supply circuit has an over-temperature fault. At this time, the server power supply circuit cannot work normally, or even if it can continue to work, the abnormality or the fault is gradually produced due to the over-current fault, or the abnormality is transmitted to the server. Therefore, it is necessary to turn off the current of the server power supply circuit by means of turning off the voltage conversion module 100 at this time to avoid further faults and damage to related components caused by the over-temperature of the first temperature. At the same time, only the output first over-temperature fault information is sent to remind the user side to check and adjust the server power supply circuit in time.

Through the above method, the first preset temperature is set to be a recovery value, and the second preset temperature is set to be an over-temperature value, so as to form a hysteresis control. The first temperature is considered normal only when the first temperature is lower than the first preset temperature, so as to ensure that the first temperature can be truly reduced to the normal temperature value by adjusting the first temperature, thereby improving the reliability.

In an embodiment, in a case that the current state information includes the second temperature of the voltage conversion module 100, the above S402 may include the following cases.

First, in a case that the second temperature is greater than a third preset temperature, it is determined that the operating state of the voltage conversion module 100 is an over-temperature alarm state, and second over-temperature alarm information is sent. The third preset temperature may be the maximum temperature value in the normal state. In a case that the second temperature is greater the third preset temperature, the over-current occurs in the voltage conversion module 100, an over-current abnormality occurs, but the server power supply circuit can still work at this time, so that only the second over-temperature alarm information is sent to remind the user side to check and adjust the voltage conversion module 100 in time.

Second, in a case that the second temperature is greater than a fourth preset temperature, it is determined that the operating state of the voltage conversion module 100 is an over-temperature fault state, and second over-temperature fault information is sent; and the voltage conversion module 100 is controlled to be turned off. The fourth preset temperature is greater than the third preset temperature. In a case that the output current is greater than the fourth preset temperature, it may be determined that the voltage conversion module 100 has an over-temperature fault. At this time, the voltage conversion module 100 cannot work normally, or even if it can continue to work, the abnormality or the fault is gradually produced due to the over-current fault, or the abnormality is transmitted to the server. Therefore, it is necessary to turn off the current of the server power supply circuit by means of turning off the voltage conversion module 100 at this time to avoid further faults and damage to related components caused by the over-temperature of the second temperature. At the same time, the output second over-temperature fault information is sent to remind the user side to check and adjust the voltage conversion module 100 in time.

Through the above method, the third preset temperature is set to be a recovery value, and the fourth preset temperature is set to be an over-temperature value, so as to form a hysteresis control. The second temperature is considered normal only when the second temperature is lower than the third first preset temperature, so as to ensure that the second temperature can be truly reduced to the normal temperature value by adjusting the second first temperature, thereby improving the reliability.

In an embodiment, FIG. 5 is a flowchart of a specific embodiment of a control method for a server power supply circuit according to an embodiment of the present disclosure. As shown in FIG. 5, in a case that the server power supply circuit is started, the control module 300 respectively samples the temperature of the voltage conversion module 100, i.e., the second temperature, the temperature of the server power supply circuit, i.e., the first temperature, the input voltage of the server power supply circuit, and the output current of the server power supply circuit, respectively performs determination thereon, and executes the steps such as the above S402 to regulate the server power supply circuit in time.

The control method for the server power supply current provided in the embodiments of the present disclosure may control the power-down holding module 200, the hot-swap module 500 and/or the voltage conversion module 100 to be turn on and/or turned off according to the current state information of the server power supply circuit, so as to process the abnormalities occurring in the server power supply circuit and improve the reliability of the server power supply circuit.

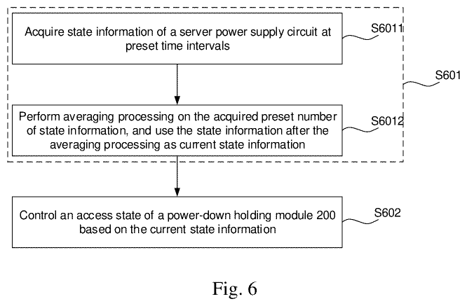

In the present embodiment, a control method for a server power supply circuit is provided, which may be configured for the above server power supply circuit. FIG. 6 is a flowchart of another control method for a server power supply circuit according to an embodiment of the present disclosure. As shown in FIG. 6, the flow includes the following steps.

At S601, current state information of the server power supply circuit is acquired.

In some embodiments, S601 includes the following operations.

At S6011, state information of the server power supply circuit is acquired at preset time intervals.

In the embodiment of the present disclosure, each piece of state information of the server power supply circuit is collected at preset time intervals. In some embodiments, an input voltage and a first temperature of the server power supply circuit, and an output current and a second temperature of a voltage conversion module 100 are respectively collected.

In an embodiment, a preset time corresponding to each piece of state information, that is, the input voltage, the first temperature, the output current, and the second temperature, that is, the sampling time may be different and may be set according to actual needs.

At S6012, averaging processing is performed on the acquired preset number of state information, and the state information after the averaging processing is used as the current state information.

In the embodiment of the present disclosure, averaging processing is respectively performed on the acquired preset number of state information, and the state information after the averaging processing is used as the current state information.

In an embodiment, a data set may be set for each piece of state information, that is, an input voltage set, a first temperature set, an output current set, and a second temperature set, and then the collected information is put into the corresponding data set respectively. At each sampling moment, averaging processing is performed on a preset number of the latest data in each data set to obtain the corresponding current state information.

In an embodiment, a corresponding sampling period may be set for each piece of state information, each piece of state information is collected a preset number of times in each sampling period, and averaging processing is performed on the state information obtained the preset number of times to obtain the current state information.

At S602, an access state of a power-down holding module 200 is controlled based on the current state information. Referring to S502 of the embodiment shown in FIG. 5 for details, which will not be elaborated here.

According to the control method for the server power supply current provided in the embodiments of the present disclosure, the current state information is obtained by a method of multiple sampling and averaging, so as to avoid the problem of inaccurate data obtained by single sampling, and improving the reliability and accuracy of the control of the server power supply circuit.

Although the embodiments of the present disclosure are described in conjunction with the drawings, those skilled in the art may make various modifications and variations without departing from the spirit and scope of the present disclosure, and such modifications and variations are all within the scope defined by the appended claims.

1. A server power supply circuit, comprising: a voltage conversion module (100), a power-down holding module (200), and a control module (300);
an input end of the voltage conversion module (100) is connected to the power-down holding module (200); the voltage conversion module (100) is configured to convert an input voltage of the voltage conversion module (100) into a target voltage; the target voltage is configured to supply power to a server;
the power-down holding module (200) is configured to hold the magnitude of the target voltage In a case that an input voltage of the circuit is powered down; the power-down holding module (200) comprises an energy storage element (210) and a power supply element (220);
a first end of the energy storage element (210) is connected to an input end of the circuit, and a second end of the energy storage element (210) is connected to the input end of the voltage conversion module (100); the energy storage element (210) is configured to store energy provided by the input voltage of the circuit and transfer the energy to the power supply element (220);
a first end of the power supply element (220) is connected to the input end of the circuit, and a second end of the power supply element (220) is connected to the input end of the voltage conversion module (100); the power supply element (220) forms a voltage by releasing the energy transferred by the energy storage element (210), so as to hold the voltage input into the voltage conversion module (100) In a case that the input voltage of the circuit is powered down, thereby holding the magnitude of the target voltage; and
the control module (300) is respectively connected to the voltage conversion module (100) and the power-down holding module (200), and the control module (300) is configured to collect current state information of the circuit, and control an access state of the power-down holding module (200) according to the current state information, so as to turn on the power-down holding module (200) In a case that the input voltage of the circuit is powered down.

2. The circuit according to claim 1, wherein the power-down holding module (200) further comprises a diversion switch (230), wherein the diversion switch (230) is configured to control the frequency and duration of energy transfer from the energy storage element (210) to the power supply element (220), so as to control the magnitude of the voltage provided by the power supply element (220);
a first end of the diversion switch (230) is connected to the second end of the energy storage element (210), and a second end of the diversion switch (230) is connected to the first end of the power supply element (220);
in a case that the diversion switch (230) is turned on, the energy storage element (210) stores the energy provided by the input voltage of the circuit; and
in a case that the diversion switch (230) is disconnected, the energy storage element (210) transfers the energy to the power supply element (220), and the power supply element (220) form the voltage by releasing the energy transferred by the energy storage element (210).

3. The circuit according to claim 1, the circuit further comprising a power-down holding switch (400), wherein a first end of the power-down holding switch (400) is connected to the power-down holding module (200), a second end of the power-down holding switch (400) is connected to the voltage conversion module (100), and a third end of the power-down holding switch (400) is connected to the control module (300); and
the control module (300) controls the connection and/or disconnection between the power-down holding module (200) and the voltage conversion module (100) through the power-down holding switch (400), so as to control the access state of the power-down holding module (200).

4. The circuit according to claim 1, wherein the power-down holding switch (400) is a transistor;
the control module (300) controls the transistor to be turned on, and controls the power-down holding module (200) and the voltage conversion module (100) to be connected, so as to control the power-down holding module (200) to be turned on;
or, the control module (300) controls the transistor to be turned off, and controls the power-down holding module (200) and the voltage conversion module (100) to be disconnected, so as to control the power-down holding module (200) to be turned off.

5. The circuit according to claim 1, the circuit further comprising a hot-swap module (500), wherein the hot-swap module (500) is respectively connected to the control module (300) and the voltage conversion module (100);
the hot-swap module (500) is configured to suppress a current spike generated by an input current In a case that the circuit is hot-swapped; and
the control module (300) is configured to control an access state of the hot-swap module (500).

6. The circuit according to claim 1, wherein the control module (300) comprises a first controller (310) and a second controller (320), wherein the first controller (310) and the second controller (320) are electrically isolated and in communication connection;
the current state information comprises an input voltage and a first temperature at the input end of the circuit, and an output current and a second temperature at an output end of the voltage conversion module (100);
the first controller (310) is connected to the input end of the circuit, and the first controller (310) is configured to collect the input voltage and the first temperature; and
the second controller (320) is connected to the output end of the voltage conversion module (100), and the second controller (320) is configured to collect the output current and the second temperature.

7. The circuit according to claim 6, wherein the first controller (310) is connected to the input end of the voltage conversion module (100); and
the first controller (310) determines an operating state of the circuit according to the input voltage, and controls the access state of the power-down holding module (200), the hot-swap module (500), and/or the voltage conversion module (100);
or, wherein the first controller (310) determines the operating state of the circuit according to the first temperature, and controls the access state of the voltage conversion module (100); and
the second controller (320) determines the operating state of the voltage conversion module (100) according to the output current and the second temperature, and controls the access state of the voltage conversion module (100).

8. (canceled)

9. A control method for a server power supply circuit, applied to the server power supply circuit according to claim 1, the method comprising:
acquiring current state information of the server power supply circuit; and
controlling an access state of a power-down holding module (200) based on the current state information.

10. The method according to claim 9, wherein the current state information comprises an input voltage at an input end of the server power supply circuit; and the controlling an access state of a power-down holding module (200) based on the current state information comprises:
in a case that the input voltage is less than a first preset voltage, determining that an operating state of the server power supply circuit is a power-down state, and sending input under-voltage alarm information; and
controlling the power-down holding module (200) and a voltage conversion module (100) to be connected, by controlling a power-down holding switch (400) to be turned on, so as to turn on the power-down holding module (200).

11. The method according to claim 10, wherein the controlling an access state of a power-down holding module (200) based on the current state information further comprises:
in a case that the input voltage is greater than or equal to the first preset voltage, determining that the operating state of the server power supply circuit is a normal state; and
controlling the power-down holding module (200) and the voltage conversion module (100) to be disconnected, by controlling the power-down holding switch (400) to be turned off, so as to turn off the power-down holding module (200).

12. The method according to claim 10, wherein the controlling an access state of a power-down holding module (200) based on the current state information further comprises:
in a case that the input voltage is less than a second preset voltage, determining that the operating state of the server power supply circuit is a complete power-down state, and sending input under-voltage fault information, wherein the second preset voltage is less than the first preset voltage; and
controlling the power-down holding module (200) and the voltage conversion module (100) to be disconnected, by controlling the power-down holding switch (400) to be turned off, so as to turn off the power-down holding module (200).

13. The method according to claim 9, further comprising:
controlling an access state of a hot-swap module (500) and/or the voltage conversion module (100) based on the current state information.

14. The method according to claim 13, wherein the current state information comprises an input voltage at an input end of the server power supply circuit; and the controlling an access state of a hot-swap module (500) and/or the voltage conversion module (100) based on the current state information comprises:
in a case that the input voltage is less than a third preset voltage, determining that the operating state of the server power supply circuit is an under-voltage state, and sending input under-voltage fault information, wherein the third preset voltage is less than the first preset voltage and greater than the second preset voltage; and
controlling the hot-swap module (500) and the voltage conversion module (100) to be turned off.

15. The method according to claim 13, wherein the current state information comprises an output current of the voltage conversion module (100); and the controlling an access state of a hot-swap module (500) and/or the voltage conversion module (100) based on the current state information comprises:
in a case that the output current is greater than a first preset current, determining that the operating state of the voltage conversion module (100) is an over-current alarm state, and sending output over-current alarm information.

16. The method according to claim 15, wherein the controlling an access state of a hot-swap module (500) and/or the voltage conversion module (100) based on the current state information further comprises:
in a case that the output current is greater than a second preset current, determining that the operating state of the voltage conversion module (100) is an over-current fault state, and sending output over-current fault information, wherein the second preset current is greater than the first preset current; and
controlling the voltage conversion module (100) to be turned off.

17. The method according to claim 13, wherein the current state information comprises a first temperature of the server power supply circuit; and the controlling an access state of a hot-swap module (500) and/or the voltage conversion module (100) based on the current state information comprises:
in a case that the first temperature is greater than a first preset temperature, determining that the operating state of the server power supply circuit is an over-temperature alarm state, and sending first over-temperature alarm information.

18. The method according to claim 17, wherein the controlling an access state of a hot-swap module (500) and/or the voltage conversion module (100) based on the current state information further comprises:
in a case that the first temperature is greater than a second preset temperature, determining that the operating state of the server power supply circuit is an over-temperature fault state, and sending first over-temperature fault information, wherein the second preset temperature is greater than the first preset temperature; and
controlling the voltage conversion module (100) to be turned off.

19. The method according to claim 13, wherein the current state information comprises a second temperature of the voltage conversion module (100); and the controlling an access state of a hot-swap module (500) and/or the voltage conversion module (100) based on the current state information further comprises:
in a case that the second temperature is greater than a third preset temperature, determining that the operating state of the voltage conversion module (100) is an over-temperature alarm state, and sending second over-temperature alarm information.

20. The method according to claim 19, wherein the controlling an access state of a hot-swap module (500) and/or the voltage conversion module (100) based on the current state information further comprises:
in a case that the second temperature is greater than a fourth preset temperature, determining that the operating state of the voltage conversion module (100) is an over-temperature fault state, and sending second over-temperature fault information, wherein the fourth preset temperature is greater than the third preset temperature; and
controlling the voltage conversion module (100) to be turned off.

21. The method according to claim 9, wherein the acquiring current state information of the server power supply circuit comprises:
acquiring state information of the server power supply circuit at preset time intervals; and performing averaging processing on the acquired preset number of state information, and using the state information after the averaging processing as current state information.
